(19) United States
(12) Patent Application Publication
(10) Pub. No.: US 2007/0018192 A1
(43) Pub. Date: Jan. 25, 2007

(54) Devices incorporating heavily defected semiconductor layers

(75) Inventors: David B. Salzman, Chevy Chase, MD (US); Eric S. Harmon, Norfolk, MA (US); Jerry M. Woodall, West Point, IN (US)

Correspondence Address: Dr. Dave S. Garrod, Esq.;Goodwin-Procter, 599 Lexington Avenue, New York, NY, 10022, US

(73) Assignee: Yale University, New Haven, CT (US)

(21) Appl. No.: 11/314,320

(22) Filed: Dec. 20, 2005

Related U.S. Application Data
(60) Provisional application No. 60/638,014, filed on Dec. 21, 2004.
(60) Provisional application No. 60/640,724, filed on Dec. 31, 2004.

(51) Int. Cl. H01L 33/00

(52) U.S. Cl. 257/103

(57) ABSTRACT

The structure and growth method are disclosed for a novel heterojunction diode structure. The invention exploits the Fermi level pinning properties of dislocations and defects in compound semiconductors to achieve heterojunctions with nonlinear current-voltage characteristics despite highly defected, polycrystalline, or amorphous semiconductors. The invention enable new diode, photodetector, and transistor devices to be implemented using highly lattice-mismatched semiconductors. The invention additionally enables thin film diodes, photodetectors, and transistors to be realized.

### CROSS-REFERENCE TO RELATED APPLICATION

This application claims priority from the U.S. Provisional Pat. App. No. 60/638,014 filed Dec. 21, 2004, “Hot Electron Transistor with Non-Lattice-Matched Semiconductor Emitter and U.S. Provisional Pat. No. 60/640,724 filed Dec. 31, 2004, “Diodes incorporating heavily defected semiconductor layers.”

### FIELD OF THE INVENTION

This invention relates generally to the fields of device physics and microelectronics, particularly to the semiconductor materials, design, structure, and fabrication of diodes, transistors and circuits containing them.

### BACKGROUND AND LIMITATIONS OF THE PRIOR ART

Junction diodes form the basis of a wide range of electronic devices. Their nonlinear current versus voltage characteristics make them useful as switches, rectifiers, electrical and optical signal detectors, and other microelectronic devices. Junction diodes can be used to modulate the channel conductivity in a field effect transistor structure. Junction transistors can be formed by a series connection of two back-to-back diodes, with the bias on the middle connection used to modulate the series current. Common junction diodes include metal-semiconductor contacts (Schottky diodes), PN (p-type-n-type) junction diodes, nN (n-type-N-type) isotype heterojunction diodes, MIM (metal-insulator-metal), NIN (n-type-insulator-n-type), PIP (p-type-insulator-p-type), and PIN (p-type-insulator-n-type) diodes. Common junction transistors include the Metal-Semiconductor Field Effect Transistor (MESFET), the Junction Field Effect Transistor (JFET), the Bipolar Junction Transistor (BJT), the Heterojunction Bipolar Transistor (HBT), and the metal-base transistor.

When diodes contain crystalline or amorphous semiconductor layers, defects within the semiconductors often degrade performance unacceptably, notably by increasing leakage currents and by acting as resistive shorts across the junction. Diodes formed with nearly perfect semiconductor single-crystals are therefore commonly preferred to the alternatives for high-performance applications.

For many applications, however, it is essential or desirable to produce junction diodes in materials that are not nearly perfect single crystals. For example, production of junction diodes using arbitrary pairs of semiconductor materials would give access to desirable properties, including availability of the semiconductor material, turn-on voltage, switching speed, blocking current, or other aspects important to semiconductor junctions. If the lattice-mismatch and thickness of the layers are such that the critical thickness for pseudomorphic growth is exceeded, lattice relaxation will occur, with a corresponding nucleation and generation of a high density of dislocations to accommodate the lattice strain. For lattice-mismatched junctions, dislocation densities in excess of 1×10⁷ cm⁻² are commonly observed, and dislocation densities at the interface between two highly lattice-mismatched semiconductors can be 1×10¹² cm⁻³ or more. (See H Tsukamoto, E-H Chen, J M Woodall, and V Gopal, “Correlation of defect profiles with carrier profiles of InAs epilayers on GaP,” Appl. Phys. Lett., 78(8) pp. 952-954 (12 Feb. 2001).) Such dislocations are generally electrically active (S D Lester, F A Ponce, M G Craford and D A Steigerwald, “High dislocation densities in high efficiency GaN-based light-emitting diodes,” Appl. Phys. Lett. 66, pp. 1249-1251 (6 March 1995) and J M Woodall, G D Pettit, T N Jackson, and C Lanza, “Fermi-Level Pinning by Misfit Dislocations at GaAs Interfaces,” Phys. Rev. Lett., 51(19), pp 1783-1786, (7 Nov. 1983); V Gupta;. E-H Chen, E P Kvam, and J M Woodall, “Behavior of a new ordered structural dopant source in InAs/(001) GaP heterostructures, J. Vac. Sci. Technol. B 17(4), pp. 1767-1772 (July/August 1999)).

The electrical activity of such dislocations acts to pin the Fermi level near a fixed position in the band gap, which makes it difficult to use extrinsic doping to achieve desired free-carrier concentrations. The defect states associated with dislocations, grain boundaries, and other semiconductor surfaces are usually sufficient to pin the Fermi level to a fixed value relative to the conduction band (or valence band) edge. This Fermi level pinning property is generally characteristic of a given semiconductor material and relatively insensitive to growth method or impurity composition(see M J Caldas, A Fazzio, and A Zunger, “A universal trend in the binding energies of deep impurities in semiconductors,” Appl. Phys. Lett., 45(6), p. 671-673 (September 1984); W Walukiewicz, “Fermi level dependent native defect formation: Consequences for metal-semiconductor and semiconductor-semiconductor interfaces,” J. Vac. Sci. Technol. B. 6(4), pp. 1257-1262(July/August 1988); and S Tiwari and D J Frank, “Empirical fit to band discontinuities and barrier heights in III-V alloy systems,” Appl. Phys. Lett. 60(5), pp. 630-632 (February 1992)).

Fermi level pinning determines the position of the Fermi level position at surfaces and defects relative to the conduction band edge (or valence band edge). In many semiconductors, this Fermi level pinning property places the Fermi level midway between the conduction band minimum and the valence band maximum, inside the forbidden band gap (M J Cohen, M D Paul, D L Miller, J R Waldrop, and J S Harris, Jr., “Schottky barrier behavior in polycrystal GaAs,” J. Vac. Sci. Technol., 17(5), pp. 899-903 (September/October 1980); J Levinson, F R Shepherd, P J Scanlon, W D Westwood, G Este, and M. Rider, “Conductivity behavior in polycrystalline semiconductor thin film transistors,” J. Appl. Phys. 53(2), pp. 1193-1202 (February 1982)).

Estimated Fermi level pinning positions of various semiconductors are listed in Table I. As can be seen from the table, most semiconductors exhibit Fermi level pinning within the forbidden band gap, and hence a high density of pinning states generally cause such semiconductors to exhibit low free-carrier concentrations and mostly insulating characteristics.

Some semiconductors (e.g. InAs and InN) exhibit Fermi level pinning positions above the conduction band minimum (see: H H Wieder, “Surface and interface barriers of InₓGa₁₋ₓAs binary and ternary alloys”, J. Vac. Sci. Technol. B 21(4), p. 1915-1919 (July/August 2003)), so a high density of pinning states causes these materials to be degenerately doped n-type and highly conductive. Similarly, some semiconductors (e.g. Ge) exhibit Fermi level pinning positions below the valence band maximum, and therefore a high density of pinning states causes these materials to be degenerately doped p-type and highly conductive.

TABLE I
Electron affinity and Fermi level pinning position
for selected semiconductors. The electron affinity [E_{C}],
valence band [E_{V}], and Fermi level [E_{F}] are
with respect to the vaccum level. All values are in electron-volts
(eV). Negative values for E_{F} − E_{C} indicate that
the Fermi level pinning position is above the conduction band
minimum (highly degenerate). Similarly negative values for
E_{V} − E_{F} indicate that the Fermi level pinning
position is below the valence maximum (highly degenerate).

| | Electron | | Valence | Fermi | | |
|---|---|---|---|---|---|---|
| | affinity | Band | Band | level | | |
| Material | [E_{C}] | gap | [E_{V}] | [E_{F}] | E_{F} − E_{C} | E_{V} − E_{F} |
| Silicon | 4.05 | 1.12 | 5.17 | 4.8 | 0.75 | 0.37 |
| Germanium | 4.0 | 0.66 | 4.66 | 4.8 | 0.8 | −0.14 |
| GaAs | 4.07 | 1.424 | 5.494 | 4.8 | 0.7 | 0.7 |
| InP | 4.4 | 1.35 | 5.75 | 4.8 | 0.4 | 0.95 |
| InAs | 4.9 | 0.35 | 5.25 | 4.8 | −0.1 | 0.45 |
| InN | 5.5 | 0.75 | 6.25 | 4.8 | −0.7 | 1.45 |

Ut s typically the case that the only effective way to achieve effective extrinsic doping in polycrystalline or heavily defected material is to develop techniques to reduce the defect density to below 10⁷ cm⁻², such as is often achieved using metamorphic growth techniques or by increasing the grain size so that the density of grains is less than 10⁷ cm⁻².

Some commercially significant applications ordinarily requiring use of highly defected or amorphous materials include thin-film diodes such as those deposited on amorphous or polycrystalline substrates, diodes using semiconductors with a large amount of lattice-mismatch either to each other, or to a substrate, semiconductor material combinations that naturally result in a high density of dislocations such as more than 10⁶, 10⁷, or 10⁸ dislocations/cm²), or polycrystalline semiconductors such as semiconductors with more than 10⁷ grains/cm².

Applications for diodes formed from highly defected or amorphous materials include thin-film displays, thin-film electronics, switches, rectifiers for rectennas, as one of the junctions in a junction transistor, as both junctions in a junction transistor, as the gate junction in a field effect transistor, and in three-dimensional integrated circuits where additional layers of circuitry are deposited on top of active circuitry.

Diodes using semiconductors with a high defect density may be grown on amorphous, polycrystalline, or single-crystal substrates, and allow integration of a wider range of semiconductors than is available in lattice-matched systems. High defect densities are generally observed for semiconductor active regions which are grown to a thickness larger than the pseudomorphic limit such that lattice relaxation occurs, causing the generation of more than 10⁷ dislocations/cm² to accommodate the strain. High defect densities are also generally observed for semiconductor active regions grown on amorphous or polycrystalline substrates, generally forming polycrystalline layers with more than 10⁷ grains/cm². Note that highly defected semiconductors also includes all classes of amorphous semiconductors, where defect densities may be hard to quantify and the material is characterized as having poor long range order. Active regions of a diode are defined as those regions within the depletion region of a diode, as well as those regions within about 100 nm of either the depletion region or the junction. Active regions of a diode also include any region of the diode where minority carriers (in bipolar devices) or hot carriers (in hot electron devices) are used to transport current.

MIM (metal-insulator-metal) diodes are well known in the prior art (see Sze, Physics of Semiconductor Devices, p. 553, 1981), where the insulator region is typically a wide band gap insulator such as SiO², AlO₂ or other metallic oxides, Si₃N₄ or other nitrides, or other amorphous or crystalline insulators, and the metal regions can be nearly any metal. MIM diodes generally rely on tunneling through the insulator region, and therefore generally exhibit low current densities and low reliability.

Single-crystal diodes including nIn diodes are also well known in the prior art (S L Feng, J Krynicki, M Zazoui, J C Bourgoin, P Bois, and E Rosencher, “Electron transport through GaAlAs barriers in GaAs,” J. Appl. Phys., 74, p. 341 (1993)). Single-crystal diodes rely on lattice-matched semiconductor layers to achieve high electrical performance, and therefore are limited to a narrow range of semiconductors that are lattice-matched and where a suitable single-crystal substrate is available.

Lattice-mismatched single-crystal semiconductors diodes are also known in the prior art (G Martin, S Strite, J Thornton, and H Morkoc, “Electrical properties of GaAs/GaN/GaAs semiconductor-insulator-semiconductor structures,” Appl. Phys. Lett. 58, p. 2375 (1991)). Such devices rely on high-temperature epitaxial grown of high-quality epitaxy, and takes advantage of the unique properties of certain heterojunctions such as GaN on GaAs growth, where the lattice ratio of cubic GaN to cubic GaAs is 4.5 Å/5.65 Å≅4/5, which allows a nearly perfect sub-lattice spacing (J Narayan and B C Larson, “Domain epitaxy:. A unified paradigm for thin film growth,” J. Appl. Phys., 93, pp. 278-285 (1 Jan. 2003).). Nearly perfect sub-lattice spacing allows high-quality GaN to be grown on GaAs and vice versa without the generation of a large density of threading dislocations. Furthermore, threading dislocations in semiconductors such as GaN appear to be significantly less electrically active then defects in other III-V semiconductors such as GaAs (S D Lester, F A Ponce, M G Craford, and D A Steigerwald, “High dislocation densities in high efficiency GaN-based light-emitting diodes,” Appl. Phys. Lett., 66(10), pp 1249-1251 (6 Mar. 1995).).

Prior art, high-performance heterojunction semiconductor devices generally require two materials to be lattice-matched or nearly lattice-matched. Lattice-mismatched materials like Si/SiGe and InGaAs/GaAs can be used only if the lattice-mismatched layers are thin enough to be pseudomorphic, so exhibit a low density of dislocations.

High-performance heterojunction bipolar transistors (HBTs) are well known in the prior art. HBTs only work well in a limited range of semiconductor materials systems where devices can be manufactured with high-quality out of single-crystals, and work poorly where the semiconductor materials are not available as single-crystals with low defect densities. Highly perfect single-crystals are necessary because crystalline imperfections such as point defects, dislocations, grain boundaries, and others act as recombination sites which reduce a microelectronic device's performance, including reduced gain and shorter mean time to failure.

There are several materials systems which could, in principle, yield HBTs with superior performance to today's best. For example, InAs, InSb, and related In-rich III-V semiconductors (including alloys of these semiconductors with other III-V semiconductors) offer unprecedented electrical transport characteristics, because their band structure discourages scattering from the primary (Γ) conduction band valley into the L and X valleys, and because the effective mass of electrons moving in the Γ valley is anomalously low. A low effective mass provides high electron mobility in general, and for hot electrons a long mean free-path. High mobility and low resistivity are also advanced by the fact that these semiconductors can be heavily doped. A similar class of high-performance semiconductors is available in certain narrow band gap II-VI materials, most notably HgCdTe and related compound semiconductors whose band gap is less than about 0.5 eV. These materials can exhibit electron mobilities in excess of 10⁴ cm/s and large separation between the primary conduction band valley and satellite valleys. Table II summarizes key properties of selected compound semiconductors, such as the high electron mobilities and peak velocities of InAs and InSb.

TABLE II
Key properties of fast III-V semiconductors

| | | | Electron | | | |
|---|---|---|---|---|---|---|
| | | | mobility for | Separation | | |
| | | | low doped, | btwn Gamma | | Thermal |
| | | | single- | valley and | Expected peak | velocity |
| | | | crystals | nearest local | velocity | electrons |
| Material | Electron mass | Band gap (eV) | (cm²/V-s) | minimum (eV) | (cm/s) | (cm/s) |
| InAs | 0.023 | 0.35 | 30,000 | 0.73 | >1.0E8 | 7.7E7 |
| InSb | 0.014 | 0.51 | 80,000 | 0.51 | ?? | 9.8E7 |
| InP | 0.08 | 0.59 | 5,000 | 0.59 | 2.5E7 | 3.9E7 |
| InN | 0.11 | 0.75 | 3,000 | | 4.0E7 | 3.4E7 |
| GaAs | 0.63 | 1.42 | 8,500 | 0.29 | 2.0E7 | 4.4E7 |

What the table does not show is that InAs, InN, and InSb suffer several drawbacks which limit the ability to use them in HBTs. These include a low band gap and poor materials quality. The low band gap causes high leakage currents in bipolar devices because the thermal generation rate for minority carriers is very high in semiconductors with a narrow band gap. The poor materials quality stems from the fact that suitably high-quality, lattice-matched (or nearly lattice-matched) heterojunctions and insulating substrates are not readily available. To achieve high-performance, InAs and InSb must be grown on lattice-mismatched, semi-insulating substrates, which is difficult and generally results in a significant density of threading dislocations that further limit performance.

Several other prior art transistor structures offer different advantages from HBTs. A hot electron transistor (HET) injects electrons with energies of at least several times kT higher than thermal electrons at the band edge. In the case of bipolar transistors, hot electrons are proposed in numerous prior art publications as a means of increasing the performance of an HBT, although in practice, only a minor improvement over non-hot electron HBTs is observed. In addition, HBTs that use hot electrons still suffer from the same limitation of other HBTs as described above, namely limitations due to the requirements for ultra-high-quality single-crystals.

Several unipolar HET devices have been proposed (See S. M. Sze, Physics of Semiconductor Devices, Chapter 9, John Wiley & Sons, New York, 1981) such as the metal base transistor using metal-insulator-metal-insulator-metal (MIMIM) or semiconductor-metal-semiconductor (SMS) structures, and single-crystal semiconductor HET devices. Currently, none of these unipolar HET devices have achieved commercial success.

Metal base transistors have not achieved commercial success for two primary reasons (S. M. Sze and H. K. Gummel, “Appraisal of Semiconductor-Metal-Semiconductor Transistor,” Solid-State Electronics, 9, pp. 751-769, 1966):
1. The mean free path of a hot electron in a metal is short, so too many hot electrons lose too much of their excess energy to be able to surmount the base-collector barrier. These carriers are lost, which reduces the HET's gain.
2. Quantum mechanical reflections arise from the large difference in electron velocity on either side of base-collector junction. These reflections represent a significant loss mechanism, particularly when trying to exploit base and collector materials with markedly distinct band structures.

Unipolar hot electron transistors using single-crystal semiconductors have also been an area of extensive research (see A F J Levi, T H Chiu, “Room-temperature operation of hot-electron transistors,” Appl. Phys. Lett. 51, 28 Sep. 1987, pp. 984-986; T H Chi and A F J Levi, “Electron transport in an AlSb/InAs/GaSb tunnel emitter hot-electron transistor,” Appl. Phys. Lett. 55, 30 Oct. 1989, pp. 1891-1893; M Heiblum and M V Fischetti, “Ballistic hot-electron transistors,” IBM J. Res. Develop. 34(4), July 1990, pp. 530-549). Single-crystal semiconductors exhibit significantly longer mean free scattering lengths but lower conductivity than metals. The longer mean free scattering length allows thicker base regions to be used, and the lower conductivity requires thicker base regions in order to maintain low base resistance. In addition, using a single-crystal semiconductor heterojunction at the base collection junction greatly reduces the quantum mechanical reflection coefficient because of the similarity of the band structures of most semiconductors. Indeed, Levi argues that it may be possible to make the quantum mechanical reflection coefficient at the base-collector junction negligible by using techniques similar to anti-reflection coatings in optics. However, prior art unipolar hot electron transistors using single-crystal semiconductors have been limited to using the same materials as conventional bipolar HBTs, which result in the following primary shortcomings:
1. Base resistance is not significantly improved over that of an HBT due to doping and mobility limitations of the materials used. While a unipolar HET uses a n-type semiconductor base region, which typically exhibits an order of magnitude higher mobility than the p-type semiconductor base region of an HBT, materials limitations often limit the doping density in unipolar HETs to an order of magnitude below that used bipolar HBTs, resulting in similar base sheet resistance. This limitation means that single-crystal unipolar HETs do not significantly outperform conventional HBTs, because the base thickness of the single-crystal unipolar HET must be similar to that of an HBT in order to achieve the same base resistance. While base transit time can be reduced in single-crystal Unipolar HET (hot electrons are generally faster than thermal electrons), the base transit time does not generally limit the performance of an HBT, so single-crystal Unipolar HETs do not achieve significantly higher speed than an HBT.
2. Due to the fact that the base region of a single-crystal Unipolar HET is relatively thick, a significant fraction of the electrons scatter and lose enough energy that they cannot surmount the base-collector junction barrier, resulting in low gain.
3. Quantum mechanical reflections at the base collector heterojunction still occur because the requirement of lattice-matching constrains matching the hot electron velocity across the junction.
4. The requirement for a high-quality, single-crystal and pseudomorphic materials has greatly limited the ability to use those semiconductor materials best suited to hot electron transistors. For example, InAs is nearly an ideal semiconductor for the base region of a Unipolar HET, and HETs using InAs have been demonstrated (see Levi references above). However, because the only semiconductor with a close lattice-match to InAs are GaSb, AlSb, and related semiconductors, performance is significantly compromised. In such lattice-matched structures, it is not possible to set the energy of the hot electrons injected from the emitter arbitrarily (due to fixed barrier heights between the emitter and base caused by the limited choice of materials), as well as fixing the barrier height between the base and collector: The hot electron energy must be far enough above the base-collector barrier energy to achieve efficient collection across this junction). While tunneling emitter contacts (see M. Heiblum and M. V. Fischetti) and barrier-lowering using reverse biasing at the base-collector junction may be used to modify the intrinsic barrier heights, such solutions only work for a limited range of bias voltages, which in turn limits the utility of such transistors for many applications. In addition, the use of antimonides greatly complicates the manufacturing process, and generally results in poor yields and high costs. Furthermore, since the choice of materials for the collector region is constrained, it also limits performance. Indeed, the collector transit time generally limits the performance of a junction transistor. For example, a collector with GaSb is typically lower performance than with GaAs, InGaAs, InAlAs, or InP.

Semiconductor crystals grown on non-lattice-matched substrates generally exhibit high density (more than 10⁷ cm⁻²) of dislocations, which accommodate the strain and lower the total energy of the system. These dislocations are generally associated with electrically active defect states, which can act as donor or acceptors (or both). The energy associated with these states can be anywhere within the forbidden band gap, as well as above the conduction band minimum or below the valence band maximum of the semiconductor.

Similarly, semiconductor crystals are grown on amorphous or non-single-crystal substrates are generally amorphous, or polycrystalline with a high density of grains (typically more than 10⁷ cm⁻²) . The defects in amorphous material and the grain boundaries in polycrystalline material exhibit electrically active states that may act as donors, or acceptors (or both), and the energy associated with these states can be anywhere within the forbidden band gap, as well as within the conduction band or valence band of the semiconductor.

### SUMMARY OF THE INVENTION

The invention enables high-performance semiconductor devices to be achieved without requiring ultra-low defect densities. Specifically, the invention enables a wide range of junction diodes, and devices using junction diodes to be achieved where the active layers of the device are not lattice-matched and are thicker than the pseudomorphic limit, resulting in layers that exhibit dislocation densities larger than 10⁸ cm⁻², grain densities larger than 10⁸ cm⁻², and/or exhibit amorphous characteristics.

An object of the invention is to allow the use of heavily defected, polycrystalline, or amorphous semiconductors to be used for junction diodes despite the presence of Fermi level pinning in these materials that prevents effective extrinsic doping.

Another object of the invention is to form junction diodes with low leakage currents despite using defected materials.

Another object of the invention is to form junction diodes in materials systems that are not lattice-matched.

Another object of the invention is to produce NIN heterojunction diodes where one or both of the N regions are not lattice-matched to the I regions.

Another object of the invention is device structures incorporating such junction diodes. These device structures include nonlinear circuit elements, switches, rectifiers, rectennas, optical detectors, transistors and other multi-junction devices, such as:

NIN Photodetectors:

i. Band-to-band absorption in the I region is readily detected as a change in conductivity between the two n-type sides of the device (photoconductive detection).
ii. Defect level-to-band absorption in the I region can be achieved. This is particularly useful for long wavelength IR detection. Absorption can be improved by increasing the density and occupancy of traps in the I-region. The resultant absorption can be detected as a change in conductivity between the two n-type sides of the device (photoconductive detection).
iii. Defect level-to-band absorption in the I region may also make use of the change in conduction through the defect states in the I-region: if the states are nearly all filled with electrons, conductivity is low because conductivity occurs via hopping of holes.

Absorption changes the concentration of holes, and the resultant conductivity change is readily detectable. Similarly, if the states are all empty (and can accept electrons), hopping conduction of electrons can occur-introduction of electrons into these states via optical absorption will result in an increase in conductivity.
iv. Absorption in an N region can be detected via an internal photoemission process, where absorption adds sufficient energy to push an electron over the NI conduction band offset barrier, and results in a measurable change in the conductivity between the two n-type sides of the device.
v. Avalanche gain in the I region can be used to provide a high-performance gain mechanism. For thin I regions, ionization can be primarily determined by the width of the I region and electron and hole feedback will be minimized, resulting in a very low excess noise factor. This effect has been shown for a number of thin gain region avalanche photodiodes.
vi. Photoconductive gain can be achieved in N1-I-N2-I-N1 devices, by storing charge in the internal (N2) node, causing a persistent change in conductivity in the outer two N-type regions (N1), persisting until the stored charge is annihilated by a recombination event.
vii. Repeating several periods of NI (i.e. 1 repeat would be NIN, 2 repeats would be NININ, 3 repeats would be NINININ . . . ) allows increased absorption to be achieved despite the fact that the N & I regions are thin enough to ensure ballistic transport—very fast devices, high gain, etc.
viii. Avalanche gain can make use of n periods to achieve periodic gain in the I-regions of the device, leading to high gain and low noise
ix. NININ version of nipi devices (using high fields in the I-region to effectively lower the band gap through Stark shift and/or real space transfer, etc.)

Note that all of the NIN devices described above can be vertical structures (three layer stack) or horizontal structures: N on top of I, where lithographic patterning of the N region is used to create lateral NIN structures.

NIN Electronic Devices:

i. Diodes and rectifiers (preferred embodiment). Note that diodes and rectifiers can be used as nonlinear devices, as switches, and as junctions in transistor structures.
ii. Three terminal devices:
   a. (N1-I-N2)—use N1 as a channel region (with 2 contacts, one for source, and one for drain) and N2 as a gate control. Modulation of the gate control bias causes a change in conductivity of the channel region via the field effect, allowing the structure to be operated as a field-effect transistor.
   b. N1-I1-N2-I2-N3 hot electron transistor, where the N2 region is the base region of a hot electron transistor. Changing the bias on N2 causes a corresponding change in the current between contacts to N1 and N3.
iii. NINININ devices. Adding more junctions can be used to produce additional devices, such as Thyristors.
   Optoelectronic Devices. Whether Photodetector or Non-Detector:
i. Use the high electrical fields possible in NIN and n-repeat patterns for optoelectronic switching.
ii. Use NIN structure inside DBR mirror structure. Modulating the bias would modulate the reflectivity by changing the optical index of refraction.
iii. Filling or emptying the deep level states in the I layer to change its refractive index in an optoelectronic modulator device.
iv. Filling or emptying the deep level states in the I layer to change its absorption, allowing an absorption modulator to be produced.

Another object of the invention is to control the conductivity of the defect states (dislocations and/or grain boundaries) by doping of the semiconductor so as to substantially fill all of the states such that hopping conduction through defect states is suppressed. Similarly, doping can be used to substantially empty all of the defect states to prevent hole conduction.

Thin Film Devices:

Due to the fact that the “N” regions can use a class of semiconductors that are capable of exhibiting both high conductivity and high electron mobilities, including InAs, InGaAs, InP, InAsP, InN, InSb, and any combination of these materials, it is possible to make thin film version of the above devices. The thin films may use amorphous, nano-crystalline, or polycrystalline layers for both the N and the I regions, with the added requirement that the N regions be chosen from those semiconductors that exhibit good amorphous or polycrystalline properties, typically arsenides, phosphides, antimonides, and nitrides where at lest 25% of the atoms in the material are indium. There are no such requirements for I regions, because many highly defected semiconductors will exhibit mostly insulating properties due to their Fermi level pinning properties, which generally place the Fermi level near the middle of the forbidden band gap.

To prevent leakage current through the mid gap defect states from dominating device performance, conductivity through these defect states should be as low as possible, which can be achieved by choosing materials with a low conductivity along grain boundaries or dislocations, or by using doping to suppress conduction along these states. Alternative means of suppressing conduction are also envisioned, including using multi-layer I structures (such as GaAs/Al_{0.5}Ga_{0.5}As/GaAs, GaA/In_{0.5}Al_{0.5}As/GaAs or n⁺-GaAs/p⁺-GaAs/n⁺-GaAs/p⁺-GaAs, etc) to block conduction through defect states. In addition, thicker I regions may be used which should further reduce the leakage current.

### BRIEF DESCRIPTION OF THE FIGURES

FIG. 1 shows the preferred embodiment. FIG. 1A shows the epitaxial layer structure, FIG. 1B shows the energy band diagram, and FIG. 1C shows the experimental current-voltage characteristics.

FIGS. 2 show several alternative embodiments. FIG. 2A shows the layer structure of one alternative embodiment with asymmetrical rectifying characteristics. FIG. 2B shows the layer structure of a different alternative embodiment with asymmetrical rectifying characteristics. FIG. 2C shows the experimental current-voltage characteristics of the alternative embodiment shown in FIG. 2B.

FIG. 3A show the layer structure of an alternative embodiment used as a photodetector. FIG. 3B shows the zero bias band diagram of the layer structure of FIG. 3A. FIG. 3C shows the band diagram of the layer structure of FIG. 3A under bias.

FIG. 4A shows the layer structure of an alternative embodiment consisting of a polycrystalline NIN junction. FIG. 4B shows another layer structure of an alternative embodiment consisting of a polycrystalline NIN junction.

FIG. 5A shows the layer structure of a lateral NIN diode in accordance with the invention. FIG. 5B shows how the layer structure of FIG. 5A can be fabricated into a lateral NIN diode.

FIG. 6A shows the layer structure of a field effect transistor where the gate junction is formed in accordance with the invention. FIG. 6B shows how the layer structure of FIG. 6A can be fabricated into a field effect transistor.

FIG. 7A shows the layer structure of a thin film transistor in accordance with the invention. FIG. 7B show how the layer structure of FIG. 7A can be fabricated into a FET device.

FIG. 8A shows the band diagram of a hot electron transistor in accordance with the invention. FIG. 8B show the layer structure of a HET in accordance with the invention.

FIG. 9A shows an alternative embodiment of the invention, a hot electron transistor using GaAs emitter, an InAs base, and an In_{0.80}Al_{0.20}As collector on a GaAs substrate. FIG. 9B shows another HET structure in accordance with the invention. FIG. 9C shows a thin film HET in accordance with the invention. FIG. 9D shows an alternative thin film HET in accordance with the invention. FIG. 9E shows another alternative thin film HET in accordance with the invention. FIG. 9F shows another alternative thin film HET in accordance with the invention.

### DETAILED DESCRIPTION OF THE FIGURES

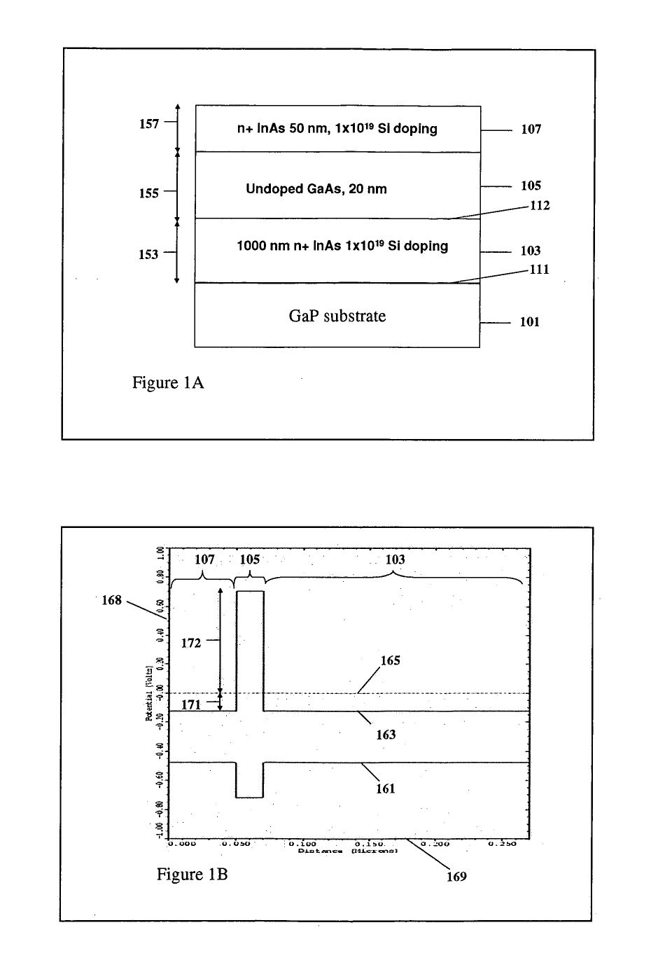

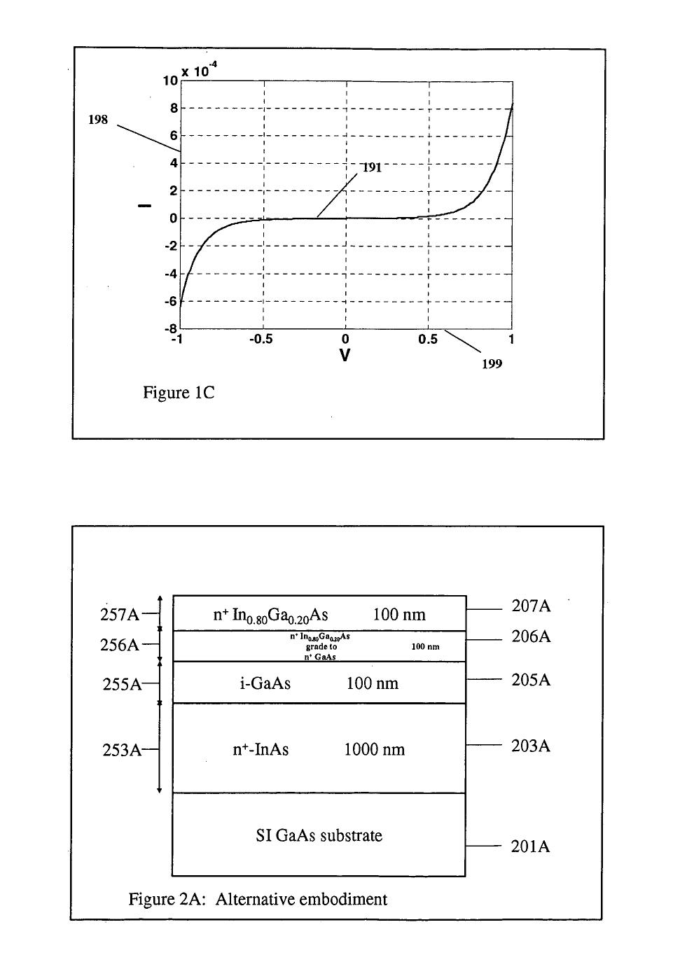

Reference is now made to FIG. 1A, which shows the layer structure of the preferred embodiment of the invention. On GaP substrate 101 was grown layer 103, consisting of a thickness 153 of 1000 nm of InAs doped n-type with 1×10¹⁹ cm⁻³ silicon using molecular beam epitaxy (J C P Chang, T P Chin, and J M Woodall, “Incoherent interface of InAs grown directly on GaP(001), Appl. Phys. Lett. v. 69, p. 981 (1996)). Due to the 11% lattice-mismatch between InAs and the GaP substrate 101, there will be a high density of threading dislocations at interface 111. These threading dislocations rapidly annihilate during the growth of layer 103, resulting in an approximate threading dislocation density of 1−10×10⁹ cm⁻² on the InAs side of interface 112 (H Tsukamoto, E-H Chen, J M Woodall, and V Gopal, “Correlation of defect profiles with carrier profiles of InAs epilayers on Gap,” Appl. Phys. Lett. 78, p. 952 (2001)). On top of the InAs layer 103 was grown GaAs layer 105 to a thickness 155 of 20 nm. Due to the 7% lattice-mismatch between GaAs and InAs, GaAs layer 105 is expected to immediately relax, producing a network of edge dislocations, as well as a threading dislocation density greater than 1×10¹⁰ cm⁻². On top of GaAs layer 105 is grown a second InAs layer 107 to a thickness 157 of 50 nm. InAs layer 107 is doped n-type with a silicon doping density of 1×10¹⁹ cm⁻³.

We note here that layers 103, 105, and 107 were grown by MBE using growth conditions that promote planar, layer by layer growth, and therefore are single-crystal. Due to the large amount of lattice-mismatch between each of the layers, strain relaxation occurs very rapidly, resulting in a high density of misfit and threading dislocations. It is worthwhile to note that these dislocations introduce deep level defects in GaAs layer 105, with the energy level of the defect being near mid gap, while dislocations introduce shallow donors states in InAs layers 103 and 107 (M J Cohen, M D Paul, D L Miller, J R Waldrop, and J S Harris, Jr., “Schottky barrier behavior in polycrystal GaAs,” J. Vac. Sci. Technol., 17, p. 899 (1980); V Gopal, E-H Chen, E P Kvam, and J M Woodal, “Behavior of a new ordered structural dopant source in InAs/(001) GaP heterostructures,” J. Vac. Sci. Technol. B. 17, p. 1767 (1999)). Therefore, the GaAs layer 105 is semi-insulating, while the InAs layers 103 and 107 are highly conductive, n-type semiconductors.

Reference is now made to FIG. 1B, showing a band diagram of the layer structure of FIG. 1A with no applied bias. . In FIG. 1B, the y-axis 168 is energy while the x-axis 169 is the vertical position within the structure. The valence band maximum is represented by 161, the conduction band minimum is represented by 163, and the Fermi level is represented by 165. Due to the heavy doping of the InAs layers (both due to the intentional silicon doping and the unintentional doping due to the dislocations), the InAs is highly degenerate with the Fermi level at least 0.1 eV above the conduction band edge 163 in layers 103 and 107. The energy difference between the Fermi level 165 and the conduction band edge in layer 107 is 171. The potential barrier between the Fermi level 165 and the conduction band edge 163 in layer 105 is 172. Since the Fermi 165 is pinned to the trapping energy of the dislocations in layer 105, the potential barrier height 172 is about 0.7 eV.

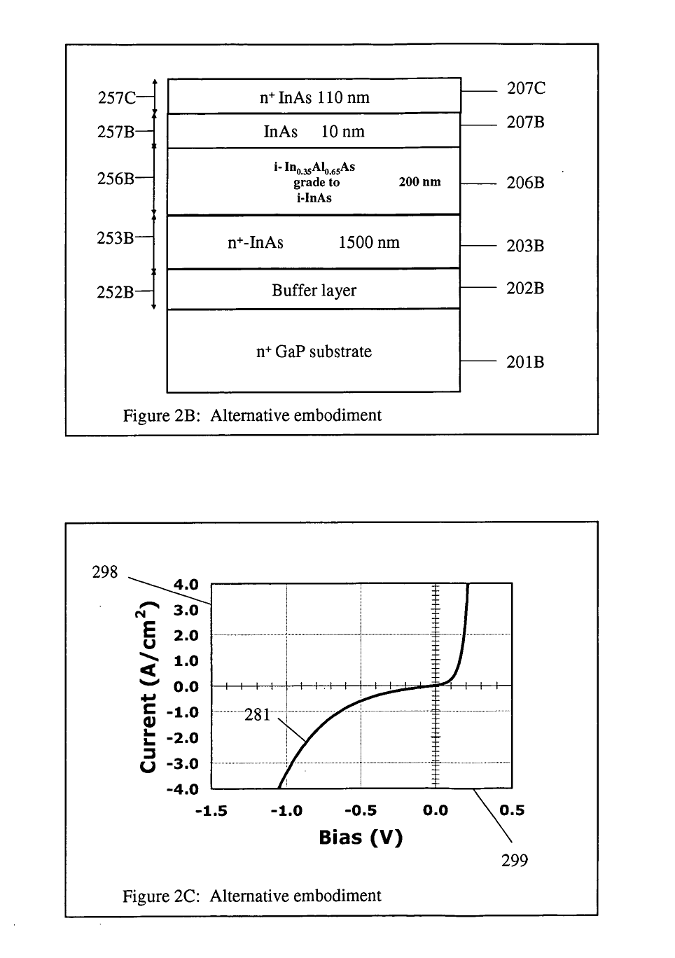

Reference is now made to FIG. 1C, showing the experimentally measured current-voltage characteristics of the layer structure shown in FIG. 1A. Ohmic contacts are made to layers 107 and 103, and mesa isolation was used to etch a circular mesa into layer 107 to define the device area. The diameter of the mesa is 40 μm. In FIG. 1C, the y-axis 198 is current while the x-axis 199 is voltage. Curve 191 is the experimentally measured current between the ohmic contacts to layers 107 and 103. The device shows excellent rectifying characteristics, with a turn on voltage between 0.5- and 1.0 Volts. Due to the degenerate doping of the n⁺ InAs layers and the mid-gap Fermi level pinning of the i-GaAs layer, the structure resembles a n-type-insulator-n-type (NIN) or metal-semiconductor-metal structure (MSM) structure, and the I-V curve is similar to what would be expected, exhibiting back to back diode characteristics. The metal-semiconductor (n⁺⁺-InAs to i-GaAs) and semiconductor-metal (i-GaAs to n⁺⁺-InAs) junctions act as diodes, with one diode reverse biased and one diode forward biased for all bias conditions. The reverse biased diode limits the current, and therefore current only flows when the reverse biased diode begins to break down. This break down may be due to avalanche break down in the i-GaAs layer 105, tunneling from one of the “metal” layers (107 or 103) into or through the i-GaAs layer 105, possibly including trap assisted tunneling from dislocation states in the i-GaAs layer 105. Due to the fact that the turn-on voltage shown in FIG. 2C is 0.5-1.0 volts, the electrons injected from one layer 105 into the other layers (107 or 103) will have excess energy, and may be used for ballistic transport through layer 107 or 103. Such hot electron transport may be useful in multiple junction devices such as hot electron transistors or multiple junction photodetectors.

Reference is now made to FIG. 2A, which shows an alternative embodiment of the invention consisting of a single NI junction. Layer 201A is a semi-insulating GaAs substrate. On top of layer 201A is grown N-type side of the junction layer 203A to a thickness 253A of 1000 nm and doped n-type with silicon to a doping density of 1×10¹⁸ cm⁻³. Those skilled in the art will observe that different doping levels and different semiconductors can be used in layer 203A. On top of N-type layer 205A is grown I-type layer 205A, consisting of undoped GaAs grown to a thickness 255A of 100 nm. On top of the I-type layer 205A is grown a graded layer 206A, where smooth compositional grading is used to grade from In_{0.8}Ga_{0.2}As (near the junction with layer 207A) to GaAs (near the junction with layer 206A). Layer 206A is undoped and grown to a total thickness 256A of 100 nm. On top of layer 206A is grown a n⁺ In_{0.8}Ga_{0.2}As contacting layer 207A, grown to a thickness 257A of 100 nm, and doped 1×10¹⁸ cm⁻³ using silicon. Graded layer 206A facilitates injection of electrons from contact 207A into the I-type layer 205A, and therefore acts as an ohmic contact to the conduction band of layer 205A. This means that the diode formed between layers 207A and 203A acts as a single NI junction, and will therefore be rectifying with a high degree of asymmetry (in contrast to the NIN diode of FIG. 1, which acts as back to back diodes, and therefore is symmetrical unless the two N regions are different).

Reference is now made to FIG. 2B, which shows an experimental realization of an alternative embodiment of the invention consisting of a single NI junction. Layer 201B is a n-type GaP substrate. On top of layer 201B is grown buffer layer 202B, consisting of a thickness 252B of 500 nm undoped Gap (adjacent to substrate 201B), followed by 20 periods of a strained layer supperlattice consisting of pairs of alternating 5 nm InAs and 5 nm In_{0.75}Al_{0.25}As layers (total thickness if 200 nm). On top of buffer layer 202B is grown an N-type contact layer 203B, which is used to form ohmic contact to the I-type side of the junction. Layer 203B in n-type InAs grown to a thickness 253B of 1500 nm and doped n-type with silicon to a doping density of 2×10¹⁹ cm⁻³. On top of layer 203B is grown the graded transition layer 206B, which provides a smooth compositional grading from InAs (near the junction with layer 203B) to n-In_{0.65}Al_{0.35}As (near the junction with layer 207B). The thickness 256B of transition layer 206B is 200 nm, and the layer is nominally undoped. On top of layer 206B is grown layer 207B, which forms an abrupt heterojunction between layers 206B and 207C. Layer 207B consists of undoped InAs grown to a thickness 257B of 10 nm. Layer 207B is grown at a reduced substrate temperature (nominally 300° C.) in order to insure that the interface between layers 207B and 206B is abrupt. On top of layer 207B is grown the n-type side of the device 207C. Layer 207C consists of n-type InAs doped with silicon to a doping density of 2×10¹⁹ cm⁻³ and grown to a thickness 257C of 100 nm.

Reference is now made to FIG. 2C, showing the experimentally measured current-voltage characteristics of the layer structure shown in FIG. 2B. Ohmic contacts are made to layers 203B and 207C, and wet chemical etching was used to etch a circular mesa into through layers 207C, 207B, and 206B to define the device area. The diameter of the mesa is 28 μm. In FIG. 2C, the y-axis 298 is current, with the plot showing a maximum current of 4 A/cm² and a minimum current of −4 A/cm². The x-axis 299 is voltage, with a minimum voltage of 1.5 V and a maximum voltage of 0.5V. Curve 281 is the experimentally measured current between the ohmic contacts to layers 207C and 203B. The device shows excellent asymetrical rectifying characteristics, with a turn-on voltage near 0.2 V, and lower reverse bias currents for voltages between −0.5 and 0 Volts. Due to the degenerate doping of the n⁺ InAs layers 207B and 207C and the mid-gap Fermi level pinning of the i-In_{0.35}Al_{0.65}As layer 206B, the structure resembles a n-type-insulator or metal-semiconductor diode structure, and the I-V curve is similar to what would be expected for a Schottky diode with a low barrier height.

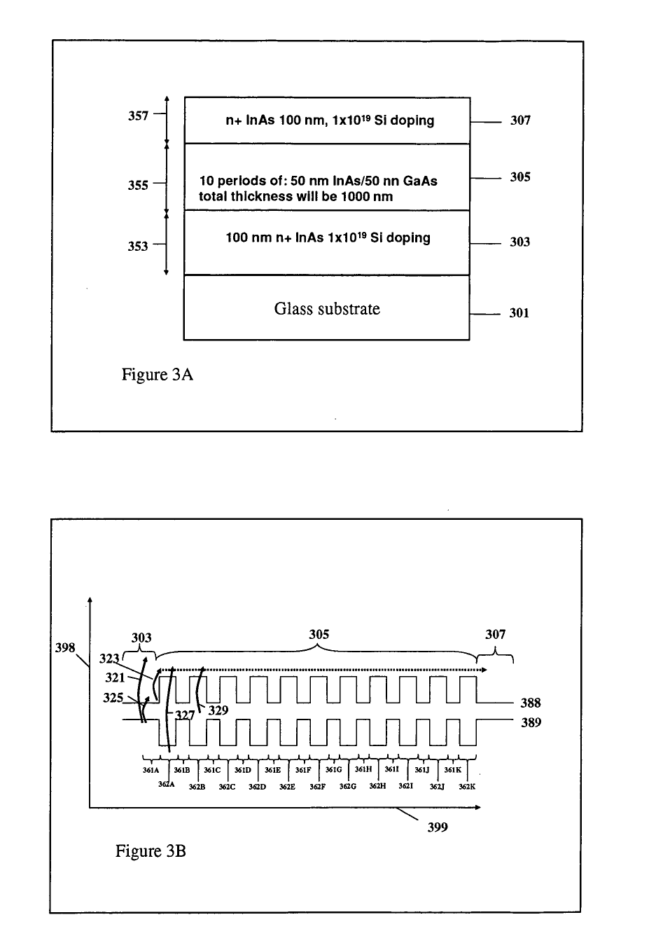

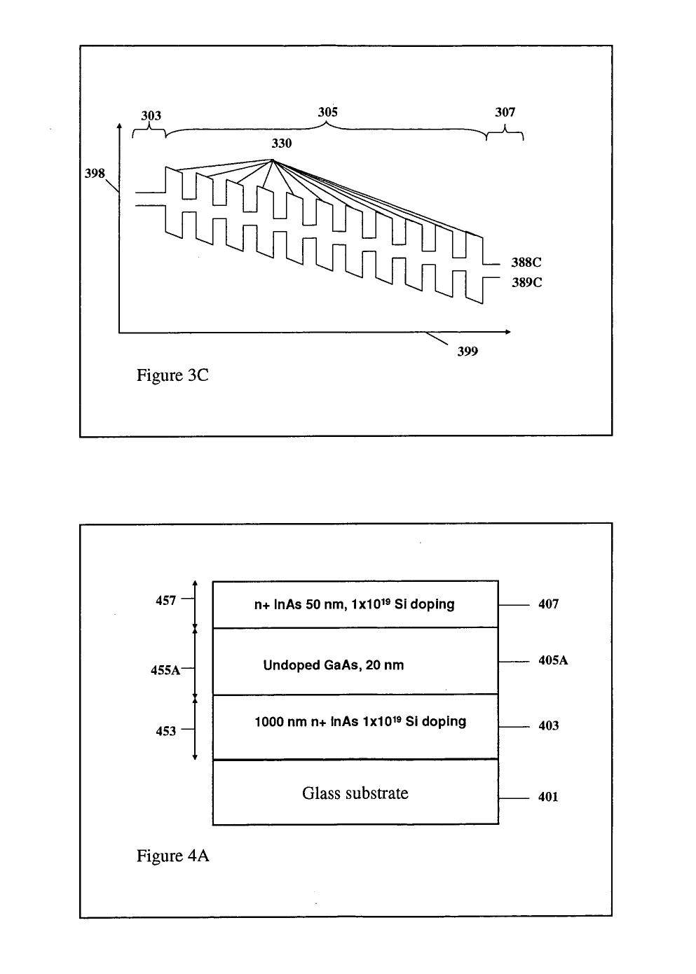

Reference is now made to FIG. 3A, showing the layer structure of an alternative embodiment consisting of a series connection of 10 NI junctions, which can be used as a photodetector. On top of glass substrate 301 is grown layer 303, consisting of a thickness 353 of 100 nm of n⁺-type InAs doped with silicon to a density of 1×10¹⁸ cm⁻³. On top of layer 303 is grown layer 305 consisting of 10 periods of alternating layers of 50 nm of n⁺ InAs doped with silicon to a density of 1×10¹⁸ cm⁻³ and 50 nm of i-GaAs that is nominally undoped. The total thickness 355 layer 305 is 1000 nm. On top of layer 05 is grown the top contacting layer 307, consisting of a thickness 357 of 100 nm of n⁺ InAs doped with silicon to a density of 1×10¹⁸ cm⁻³.

Reference is now made to FIG. 3B, showing the zero bias band diagram of FIG. 3A, showing energy 398 as a function of depth 399 with the layer. The conduction band edge is represented by 388, and the valence band edge is represented by 389. Transistion 321 shows how absorption of a photon with sufficient energy can promote an electron from the valence band of the InAs layer 361A to an excited state in the conduction band of InAs layer 361A with sufficient energy that it can surmount the potential barrier of the conduction band offset to the adjacent GaAs layer 362A and can therefore be collected as a photo current. Transistion 323 shows how free-carrier absorption of a photon with sufficient energy can promote a thermal electron from the conduction band of the InAs layer 361A to an excited state in the conduction band of InAs layer 361A with sufficient energy that it can surmount the potential barrier of the conduction band offset to the adjacent GaAs layer 362A and can therefore be collected as a photo current. Transition 325 shows how absorption of a photon with insufficient energy can promote an electron from the valence band of the InAs layer 361A to an excited state in the conduction band of InAs layer 361A with insufficient energy to surmount the potential barrier of the conduction band offset to the adjacent GaAs layer 362A. Note that similar transitions can occur in any one of the other 9 periods of InAs (layers 361B, 361C, 361D, 361E, 361F, 361G, 361H, 361I, 361J, 361K). Transition 327 shows how absorption of a photon with energy in excess of the band gap of the GaAs layer 362A can also contribute to the photocurrent. Transition 329 shows how absorption of a photon with energy below the band gap of the GaAs layer 362B can contribute to the photocurrent if he transition takes place between a deep level defect state within the band gap of layer 362B to above the conduction band edge of layer 362B. Due to the lattice-mismatch between the alternating InAs and GaAs layers, there were be a high density of misfit and threading dislocations, which create a high density of deep level defect states which will increase the absorption coefficient for photons with sub-band gap energy. Note that similar transitions can occur in any one of the other of the GaAs periods (layers 362A, 362B, 362C, 362D, 362E, 362F, 362G, 362H, 362I, 362J, 362K).

Reference is now made to FIG. 3C, showing the band diagram of FIG. 3B under bias. The applied bias causes the conduction band edge 388C and valence band edge 389C to be sloped as shown in the figure. The bias creates an electric field in the i-GaAs regions, which appears as a slope 330 to the conduction band edge of the GaAs regions. Note that the electric field (and hence slope in the band edges) in the InAs regions is much smaller, because the applied field is screened by the doping in the InAs regions. If the electric field 330 is sufficiently high, electrons in these regions can be accelerated to sufficient energy to cause impact ionization and therefore avalanche gain. In addition, each of the GaAs regions may be made thin enough that the number of impact ionization events per pair of InAs/GaAs (NI) junctions is more precisely deterministic than the number of impact ionization events in bulk GaAs, resulting in a lower excess noise factor.

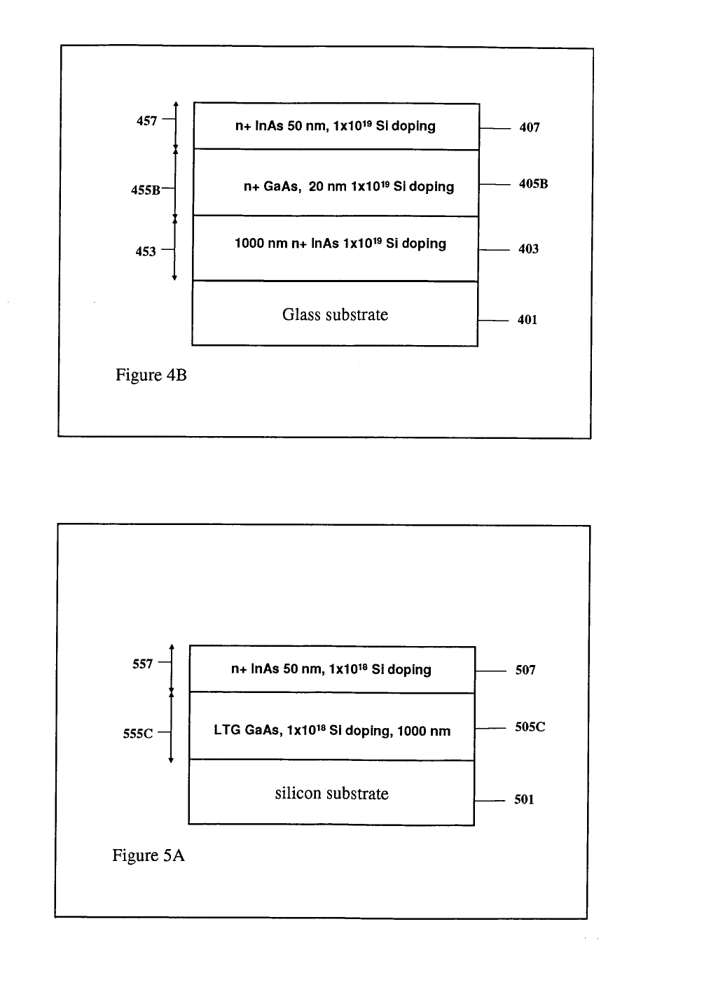

Reference is now made to FIG. 4A shows an alternative embodiment consisting of a polycrystalline NIN junction on an amorphous glass substrate 401. On top of substrate 401 is deposited n⁺ InAs layer 403, deposited to a thickness 453 of 1000 nm and doped with 1×10¹⁸ cm⁻³ silicon atoms. On top of layer 403 is deposited an undoped GaAs layer 405A, deposited to a thickness 455A of 20 nm. On top of GaAs layer 405A is deposited an n⁺ InAs layer 407 deposited to a thickness 457 of 50 nm and doped 1×10¹⁸ cm⁻³ with silicon. This layer structure forms a NIN diode on an amorphous substrate. Due to the shallow donor characteristic of dislocations and grain boundaries in InAs layers 403 and 407 and the deep level traps of dislocations and grain boundaries in GaAs layer 405A, this layer structure exhibits the appropriate NIN sequence of conductivity. For highest performance, the density of dislocations and polycrystalline grain boundaries in layer 405A should be relatively low, because conduction along grain boundaries and dislocations generally cause an undesirable leakage current component.

Reference is now made to FIG. 4B, showing a modification to the layer structure in FIG. 4A that can be advantageously used to lower the conduction along grain boundaries and dislocations. The layer structure is identical, with the exception of layer 405B, which replaces layer 405A of FIG. 4A. Layer 405B consists of n⁺ GaAs, deposited to a thickness 455B of 20 nm and doped with 1×10¹⁹ cm⁻³ silicon atoms. The silicon atoms donate electrons to the conduction band, which then become trapped at the deep level states of the GaAs. If the doping density of layer 405B is sufficient to fill a sufficient number of the deep level states, conduction through these states can be greatly reduced because conduction generally requires the availability of nearby empty states. Therefore, it is desirable to balance the density of deep level states with the density of n-type doping to achieve as high an occupancy of deep levels as possible.

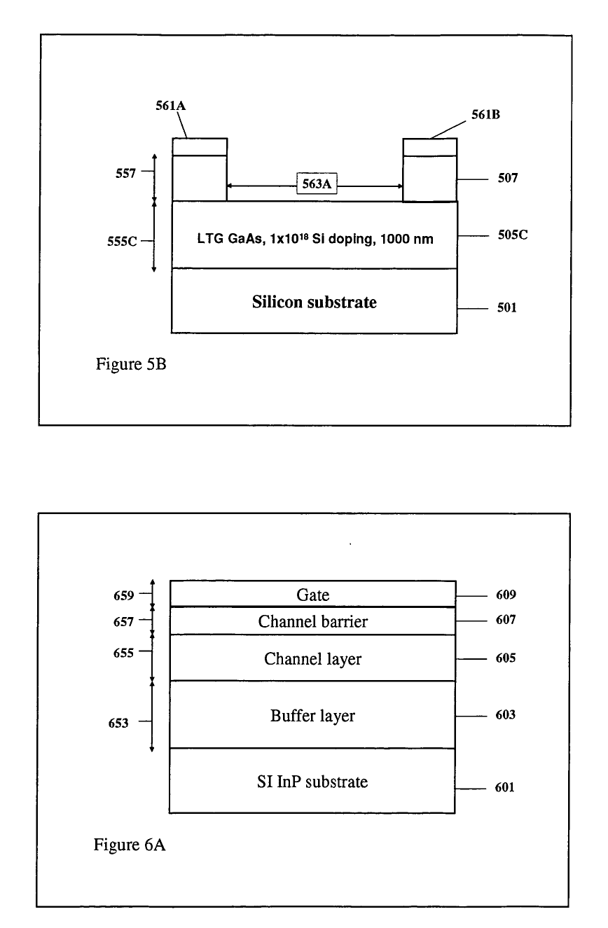

Reference is now made to FIG. 5A, showing the layer structure of an alternative embodiment, consisting of a low temperature growth GaAs layer 505C grown on a silicon substrate 501. In addition to the dislocations due to the lattice-mismatch between the silicon substrate 501 and the GaAs layer 505, low temperature growth GaAs (LTG-GaAs) introduces additional deep level states into the GaAs, which are known to produce highly insulating GaAs upon anneal. The substrate temperature during the growth of layer 505C should be less than about 350° C. to promote the incorporation of excess arsenic during growth, which are incorporated as arsenic antisites and gallium vacancies, both of which are deep levels. Similar to the case of FIG. 4B, doping of layer 505C with 1×10¹⁸ cm⁻³ silicon atoms can be used to increase the occupancy of deep levels in the GaAs layer and thereby lower the conductivity through the defect states. Additionally, the use of LTG-GaAs allows the use of a post growth anneal to be used to redistribute the excess arsenic in the layer, and a substantial fraction of the excess arsenic will precipitate into metallic clusters, which can be used to modify the density of deep states in the layer. The thickness 555C of layer 505C is 1000 nm. On top of layer 505C is deposited a n⁺ InAs layer 507, grown to a thickness 557 of 50 nm and incorporating 1×10¹⁸ cm⁻³ silicon atoms.

Reference is now made to FIG. 5B, showing how the layer structure of FIG. 5A can be fabricated into a lateral NIN diode. Metallic contacts 561A and 561B are deposited on top of layer 507 using conventional metal deposition techniques. Due to the pinning of the Fermi level in InAs, a wide range of metals such as Au, Ni, Al, Ti, Pd, W, etc., readily make low resistance ohmic contacts to layer 507. Using standard photolithography techniques, metal contacts 561A and 561B are defined as shown in the figure, with a spacing 563A between contacts. Next, the portion of InAs layer 507 between the metal contacts 561A and 561B is removed, eliminating the ohmic conduction path through layer 507 for contacts 561A and 561B. Conduction between contacts 561A and 561B will therefore have to include conduction through layer 505C, and therefore this structure forms a lateral NIN diode. We note here that this structure allows formation of NIN diodes on top of crystalline silicon, which can be useful for three dimensional integration applications such as flash memory. In addition, this lateral NIN diode is suitable as a long wavelength photoconductive detector, because the deep levels in the GaAs layer 505C can absorb photons with energies as small as 0.7 eV, similar to transition 325 in FIG. 3B. Thus, this layer structure provides a means of developing a long wavelength photodetector on silicon. Very high sensitivity is feasible because the resistivity of the defect conduction mechanism can be kept very high by the doping compensation technique described in FIG. 4B.

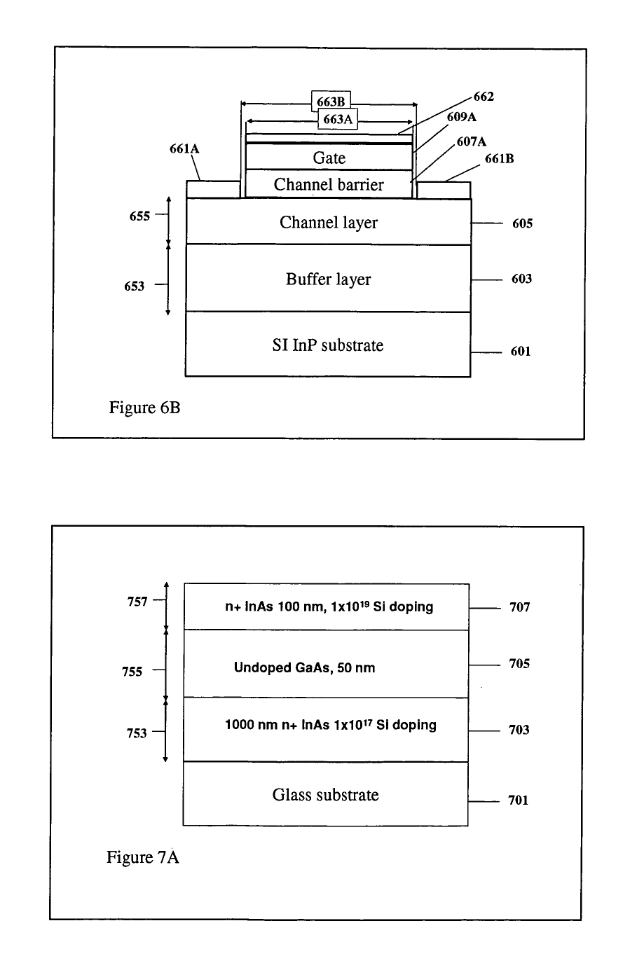

Reference is now made to FIG. 6A, showing the layer structure of an alternative embodiment, where a highly defected layer is incorporated as the gate region of field effect transistor. The structure of a buffer layer 603 grown on a semi-insulating InP substrate 601 to a thickness of 653. The buffer layer is used to promote the growth of the overlying layers 605, 607, and 609, and should be made as insulating as possible to prevent parasitic current flow. Examples of buffer layers compatible with substrate 601 are InP and InAlAs grown lattice matched to InP. A particularly advantageous buffer layer 603 can be formed from lattice matched InAlAs, grown by MBE at a low substrate temperature in order to achieve incorporation of excess As, which causes buffer layer 603 to be highly insulating. The thickness 653 of buffer layer 603 is chosen to achieve the goals of promoting the growth of the overlying layers and providing a high isolation, and is generally in the range of 100 nm to 1000 nm. On top of buffer layer 603 is grown the channel layer 605 which is grown to a thickness 655. The material in the channel layer 605 is chosen such that it is either lattice matched to buffer layer 603, or that the lattice mismatch is small enough and the thickness 655 is small enough to allow the layer to be pseudomorphic and prevent the formation of a significant number of dislocations. In general, layer 605 will be formed from InP, InₓGa₁₋ₓAs, or In_{y}As_{1-y}P, or InGaAsP, with the exact material composition chosen to achieve the desired properties of mobility, band gap, breakdown strength, saturated drift velocity, band offsets, and other properties know to be advantageous by those skilled in the art. On top of layer 605 if grown the wide band gap channel barrier layer 607, grown to a thickness 657. Layer 607 can be used as a spacer to separate the channel region from the gate, can be used to increase the barrier height to the gate in order to lower gate leakage currents, and can be used as a source of dopants to modulation dope channel region 605. Those skilled in the art will recognize that modulation doping advantageously increases the mobility and free carrier concentration in the channel region of a FET, and the dopant atoms providing the modulation doping can be inserted either layer 607, 603, or both. Layer 607 can be formed from any semiconductor that provides a suitable barrier to the channel. In an advantageous embodiment of the invention, layer 607 can be formed from In_{z}Al_{1-z}As, with z<0.50, with the thickness 657 kept below the pseudomorphic limit to insure that dislocations generated by the lattice mismatch are not significant. Those skilled in the art will recognize that the strain of the lattice mismatch in layer 607 can be made to counterbalance the strain of layer 605 to reduce the total strain of the combined layer stack. In another embodiment in accordance the invention, layer 607 can be formed for AlGaAs, which will typically be grown to a thickness 657 larger than the pseudomorphic limit and will therefore exhibit a high density of dislocations, but is capable of isolating channel 605 from gate 609 as shown in FIGS. 1A-1C. On top of the channel barrier layer 607 is grown the gate layer 609 to a thickness 659. In an advantageous embodiment of the invention, gate layer 609 is formed from heavily doped, n-type InAs, which can be made to exhibit high conductivity as well as a large potential barrier with layer 607, reducing the gate leakage current.

Reference is now made to FIG. 6B, showing how the layer structure of FIG. 6A can be fabricated into a field effect transistor. Metal gate contact 662 is deposited on top of gate layer 609, and patterned using standard photolithography as shown in the figure. The lateral extent of the metal gate contact is 663A. Because gate layer 609 is chosen from those semiconductors that exhibit Fermi level pinning above the conduction band minimum (or below the valence band maximum), it is straightforward to achieve low resistance ohmic contact to the gate without annealing or alloying of the contact. Standard mesa etching techniques can be used to define gate mesa 609A and channel barrier mesa 607A with lateral extent 663A, which may be self-aligned to gate contact 662 simply by using gate contact 662 as the etching mask. Metallic source contact 661A and drain 661B are deposited directly on top of channel layer 605 using conventional metal deposition techniques. Contacts 661A and 661B can be formed using materials that, upon anneal will alloy with channel layer 605, lowering their resistance. In some embodiments, annealing will not be necessary because the surface Fermi level pinning properties of channel layer 605 readily promote low resistance ohmic contacts without requiring high temperature annealing. Standard photolithography techniques are used to define the source contacts 661A and drain contact 661B are defined as shown in the figure, with a lateral spacing 663B between contacts. Conduction between source contacts 661A and drain contact 661B can be modulated through field effect modulation of the conductivity of channel 605. Field effect modulation of the conductivity of channel 605 is achieved by applying a bias to gate contact 662, and therefore the structure operates as a field effect transistor.

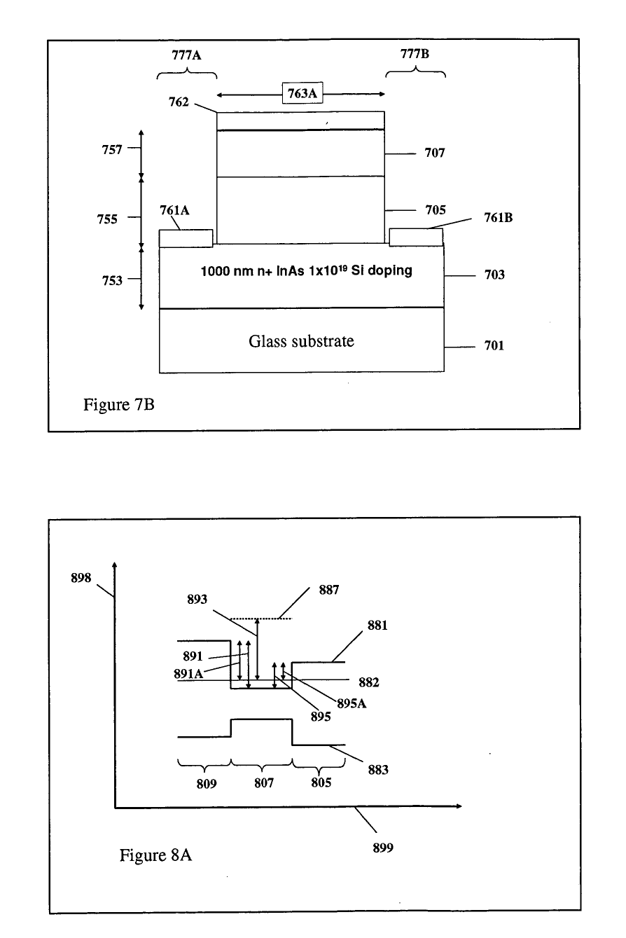

Reference is now made to FIG. 7A, showing the layer structure of a thin film FET structure in accordance with the invention. On top of glass substrate 701 is deposited n⁺ InAs channel layer 703, deposited to a thickness 753 of 1000 nm and doped n-type with silicon to achieve a free carrier density of 1×10¹⁷ cm⁻³. On top of channel layer 703 is deposited an undoped GaAs channel barrier layer 705, deposited to a thickness 755 of 50 nm. On top of channel barrier layer 705 is deposited an n⁺ InAs gate layer 707, deposited to a thickness 757 of 100 nm and doped n-type with silicon to a doping density of 1×10¹⁹ cm⁻³.

Reference is now made to FIG. 7B, showing how the layer structure of FIG. 7A can be fabricated into a FET device. First, gate contact 762 is deposited on top of n⁺ InAs gate layer 707, and standard lithographic techniques are used to define the gate width 763A as shown in the figure. Next, gate layer 707 and channel barrier layer 705 are removed from the source region 777A and drain region 777B, and source contact 761A and drain contact 761B are deposited. Due to the Fermi level pinning in InAs, contacts 761A, 761B, and 762 can be formed in a wide range of suitable metals, and will readily form low resistive ohmic contact to their respective layers. Field effect modulation of the channel 703 conductivity can be achieved by applying a bias to gate contact 762, effectively modulating the conductivity between source contact 761A and drain contact 761B.

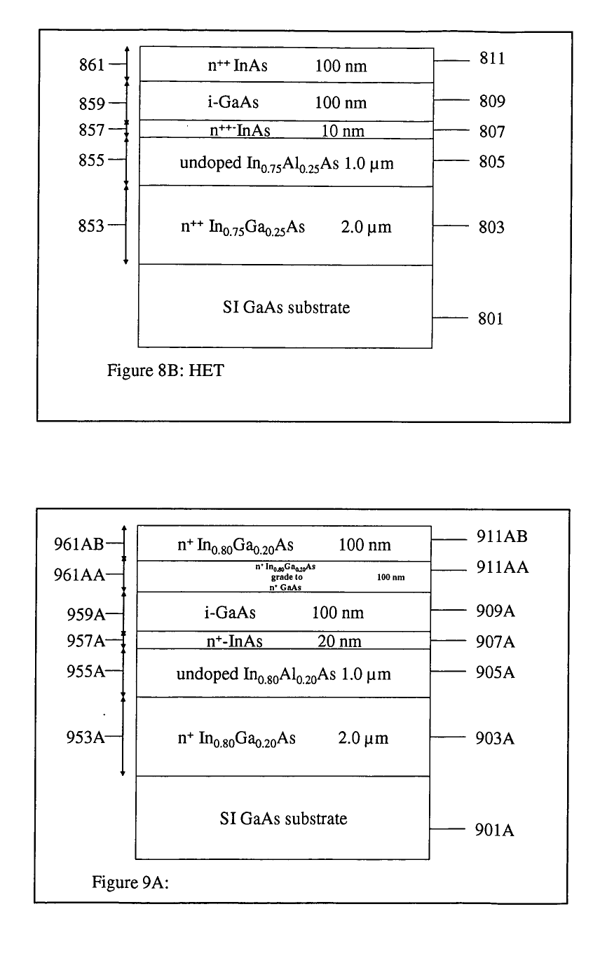

Reference is now made to FIG. 8A, which shows a schematic of a desirable band diagram of a HET in accordance with the invention. The design constraints of a high performance HET are well known (see Levi and Heiblum references). The y-axis 898 is energy and the x-axis 899 is the vertical depth within the device. Region 809 is the emitter region, 807 is the base region, and 805 is the collector region (not to scale). The conduction band edge is 881, the valence band edge is 883, and the Fermi level is 882. In the base region 805, the diagram also shows the next lowest energy conduction band minim in the base region, represented by the energy level 887. The conduction band offset between the emitter region 809 and the base region 805 is 891, while the energy difference between the emitter band edge and the Fermi level 882 is 891A. The conduction band offset between the conduction band edge in the base region 807 and the conduction band edge in the collector region 805 is 895, while the energy difference between the Fermi level 882 and the collector band edge in the collector region 805 is 895A. Note that in this simplified representation, no band bending is shown, but in the general case band bending may occur near the junction to accommodate any difference between the Fermi level positions relative to the vacuum level across the junctions. Electrons are injected from the emitter 809 into the base 807 with an excess energy determined by 891A. Note that the thermal distribution of electrons in emitter layer 809 will actually result in a spread of injected energies that decays exponentially above the conduction band energy as a function of kT. To achieve high performance HET operation, the base-collector barrier height 895 should be significantly lower than conduction band offset 891 at the emitter-base junction, which is used to inject hot electrons from the emitter region 809 into the base region 805, in order to improve the collection efficiency of the hot electrons in the base. This is because some of the hot electrons injected with excess energy 891A will scatter and lose energy as they transit the base region 807. If these electrons then have an energy less than about 895A at the base-collector junction, they will not have sufficient energy to surmount the base collector barrier, and will therefore be lost. Therefore it is desirable to have the potential barrier height 895 be as low as possible. However, the potential barrier 895 must be high enough to prevent the injection of thermal electrons from the base region 807 into the collector region 805. Since thermal electrons have a Fermi distribution above the Fermi level 882, the barrier height 895A should be at least 10 kT above the Fermi level 882. In addition the excess energy 891A of electrons injected into the base 807 should be less than about 893. If the excess energy 891 is higher than 893, the scattering rate into the alternative conduction band minimum 887 is increased. Electrons that do scatter into conduction band minimum 887 will exhibit low mobility, lower velocity and enhanced scattering, reduce the fraction of electrons that transit across the base with sufficient energy to surmount the base-collector barrier 895, and increasing the transit time delay through the base region 807.

While the optimizations described above are well known, it is difficult to achieve a high performance band structure as described for FIG. 1 because of the limitations of lattice-matched materials. Further requirements for high performance include low scattering rates and high conductivity of the base region 807. Low scattering rates increase the mean free path of electrons, and allow thicker base regions to be used, while high conductivity reduces the base access resistance and allows thin base regions to be used, increasing the base transport factor and decreasing the loss of high energy electrons. In addition, the semiconductor material used for collector layer 805 should exhibit high electron transport performance, including high saturated drift velocities and high breakdown strength. A high saturated drift velocity reduces the transit time for electrons to traverse the collector layer 805, while a high breakdown strength enables the use of thin collector regions without exhibiting avalanche breakdown during operation, which also increases the collector transit time. We also note that it is sometimes desirable to use thicker collector regions 805 in order to decrease the collector capacitance, because a high collector capacitance often lowers the maximum operating frequency. An important trade off can be made in hot electron transistors—a higher collector capacitance can be compensated by a lower base resistance, resulting in higher performance.

The invention solves the limitations of the prior art in several ways: First, it removes certain traditional limits on the choice of materials eligible for the base, emitter, and collector region of a hot electron transistor, thereby allowing high performance semiconductors such as InAs to be used in the base. Second, it relaxes the constraint requiring a semiconductor emitter to be nearly lattice-matched to the base and/or collector.

A means of producing high performance, non-lattice-matched semiconductor emitter regions is disclosed. These non-lattice-matched emitters enable HET devices to be produced with higher performance than prior art devices.

The layer structure of a HET in accordance with the invention is shown in FIG. 8B. The structure is grown on a semi-insulating GaAs substrate 801 using conventional epitaxial growth techniques such as molecular beam epitaxy (MBE) or chemical vapor deposition (CVD). On top of substrate 801 is grown an n-type In_{0.75}Ga_{0.25}As collector layer 803 grown to a thickness 853 of 2.0 μm and doped with silicon to a doping density of 1×10¹⁹ cm⁻³. Thickness 853 was chosen to provide a reasonable compromise between processing complexity, layer 803 resistance, and defect density at the interface between layers 803 and 805. Growing thicker layers decreases this defect density and the layer 803 resistance, but increases processing complexity. The In mole fraction of layer 803 was chosen to be 75% because this allows growth of collector region 805 that is lattice-matched to layer 803. While such lattice matching is not required, the use of lattice matching between layers 803 and 805 enables layer 805 to exhibit optimal transport properties, thereby improving transistor performance. Therefore, layer 805 consists of undoped In_{0.75}Al_{0.25}As grown to a thickness 855 of 1.0 μm. On top of layer 805 is grown the n⁺⁺ InAs base layer 807, grown to a thickness of 857 and doped with silicon to a doping density of 1×10¹⁹ cm⁻³. While layer 807 is not lattice-matched to layer 857, thickness 855 is below the pseudomorphic limit, which can allow the base to be a high quality, low defect density single-crystal. On top of layer 807 is grown the i-GaAs emitter layer 809 to a thickness 859 of 100 nm. Due to the large lattice-mismatch between layers 807 and layer 809, we expect lattice relaxation to occur within the first few monolayers of growth, resulting in the generation of a dense network of edge and threading dislocations near the interface between layers 807 and 809. As shown in FIGS. 1A, 1B, and 1C, this junction still exhibits excellent rectification characteristics. Finally, on top of layer 809 is grown a n⁺⁺ InAs layer 811, doped n-type with silicon to a doping density of 1×10¹⁹ cm⁻³ and grown to a thickness 861 of 100 nm. The layer structure of FIG. 8B achieves the desirable band structure of a HET shown in FIG. 8A.

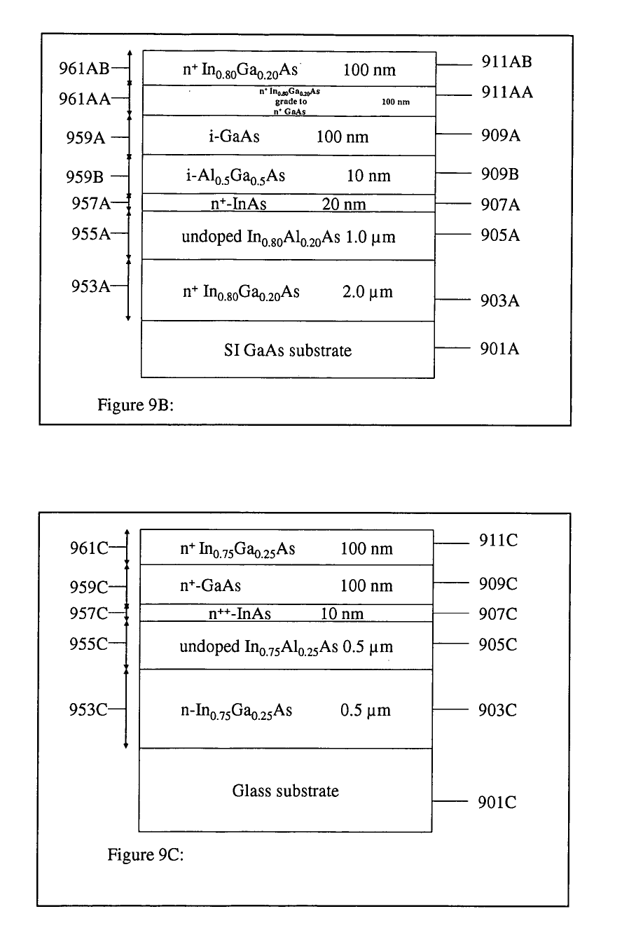

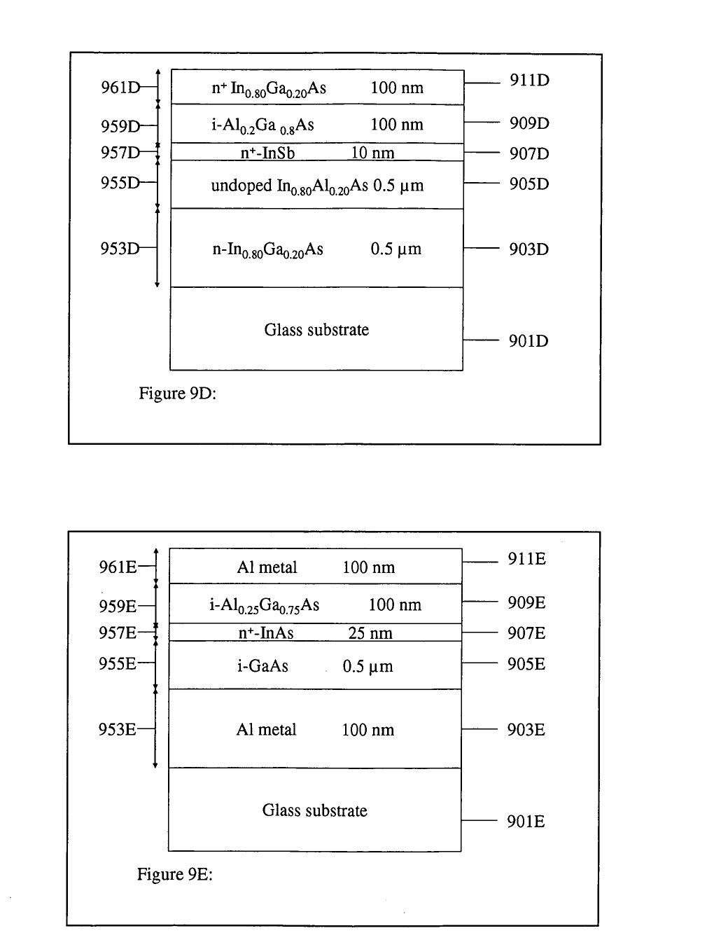

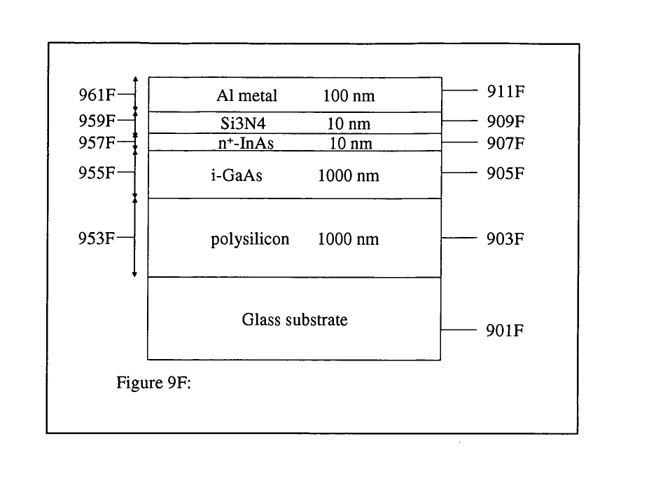

Reference is now made to FIG. 9A, which shows another HET structure in accordance with the invention. Layer 901A is a semi-insulating GaAs substrate, layer 903A is a n-type In_{0.80}Ga_{0.20}As buffer/contacting layer grown to a thickness 953A of 2.0 μm, doped n-type with 1×10¹⁸ cm⁻³ silicon atoms. On top of layer 903A is grown the collector layer 905A, consisting of a thickness 955A of 1.0 μm of undoped In_{0.80}Al_{0.20}As. On top of layer 905A is grown the base layer 907A to a thickness 957A of 20 nm and doped n-type with silicon to a doping density of 1×10¹⁸ cm⁻³. Those skilled in the art will observe that different base dopings can be used, provided that the base resistance remains sufficiently low to achieve high frequency operation. In some cases, it may be advantageous to use modulation doping of the base, such as can be achieved by heavily doping a portion of emitter layer 909A n-type, with the free electrons created by the doping being transferred to the InAs base region. Furthermore, we note that very low resistance ohmic contacts can be readily made to the InAs base region due to the high electron affinity of InAs, and the Fermi level pinning of InAs surfaces, where the pinning level is above the conduction band edge. This allows nearly any metal to be used for ohmic contacts, and not annealing of the contacts is necessary, which facilitates using very thin base regions, where alloyed contacts have the potential to cause a short between the base and collector. On top of base layer 905A is grown emitter layer 909A, consisting of undoped GaAs grown to a thickness 959A of 100 nm. On top of the emitter layer 909A is grown a graded layer 911AA, where smooth compositional grading is used to grade from In_{0.8}Ga_{0.2}As (near the junction with layer 911AB) to GaAs (near the junction with layer 909A). Layer 911AA is undoped and grown to a total thickness 961AA of 100 nm. On top of layer 911AA is grown a n⁺ In_{0.8}Ga_{0.2}As contacting layer 911AB, grown to a thickness 961AB of 100 nm, and doped 1×10¹⁸ cm⁻³ using silicon. Graded layer 911AA facilitates injection of electrons from contact 911AB into emitter layer 909A, and therefore does not rely on the reverse bias breakdown characteristics of the junction between layers 909 and 911.

Reference is now made to FIG. 9B, showing another HET structure in accordance with the invention. This embodiment is identical to that shown in FIG. 9A, with the exception of the addition of layer 909B between layers 907A and 909A. Layer 909B is an undoped Al_{0.5}Ga_{0.5}As layer grown to a thickness 959B of 10 nm. This layer is used to provide a tunnel barrier between the emitter region 909A and the base region 907A. The use of a tunnel barrier advantageously reduces the spread in the direction of the electron velocity of electrons entering the base region 907A, causing the electron trajectory to be more focused towards collector layer 905A, and reducing the fraction of electrons with excessive lateral momentum. Those skilled in the art will recognize that other tunnel barrier structures may be used, such as a double barrier resonant tunneling structure.

Reference is now made to FIG. 9C, showing a thin film HET in accordance with the invention. Due to the fact that the invention tolerates lattice-mismatched growth and high densities of defects, the invention may be used to make thin film transistors using polycrystalline materials. On top of a glass substrate 901C is grown an undoped In_{0.75}Ga_{0.25}As layer 903C grown to a thickness 953C of 0.5 μm. On top of layer 903C is grown an undoped In_{0.75}Al_{0.25}As layer 905C grown to a thickness 955C of 0.5 μm. On top of layer 905C is grown the InAs base layer 907C to a thickness 957C of 10 nm. On top of base layer 907C is grown the GaAs emitter layer 909C grown to a thickness 959C of 100 nm. On top of emitter layer 909C is grown the i-In_{0.75}Ga_{0.25}As emitter contacting layer 911C to a thickness 961C of 100 nm. Note that the polycrystalline grain boundaries in layer 903C and 911C will exhibit Fermi level pinning positions near the conduction band edge, effectively doping the layers n-type. Grain boundaries in layer 907C will exhibit Fermi level pinning positions above the conduction band edge, causing this layer to be heavily doped n-type. Grain boundaries in layers 905C and 909C will pin the Fermi level near mid-gap, causing these layers to exhibit very low free carrier concentrations, and can be considered insulating. Some modification of the doping can be achieved by varying the grain sizes, with larger grain sizes exhibiting less grain boundary surface area, and therefore lower effective doping. Larger grain sizes may help reduce parasitic leakage currents through layers 905C and 909C, improving performance. Those skilled in the art will recognize that doping levels may also be modified by using intentional doping, and intentional doping of layers 905C and 909C may be used to compensate some of the mid gap trapping levels caused by the grain boundaries, which can be used to reduce parasitic conduction along grain boundaries.

Reference is now made to FIG. 9D, shows an alternative thin film HET structure in accordance with the invention. On top of substrate 901D is grown the n-In_{0.8}Ga_{0.2}As collector contact layer 903D to a thickness 953D of 0.5 μm and doped with 1×10¹⁹ cm⁻³ silicon atoms. On top of layer 903D is grown the i-In_{0.8}Al_{0.2}As collector layer 905D to a thickness 955D of 0.5 μm and is nominally undoped. On top of layer 905D is grown the n⁺ InSb base layer 907D to a thickness 957D of 10 nm and doped 1×10¹⁹ cm⁻³ silicon atoms. On top of layer 907D is grown the i-Al_{0.2}Ga_{0.8}As emitter layer 909D to a thickness 959D of 100 nm and is nominally undoped. On top of layer 909D is grown the n-In_{0.8}Ga_{0.2}As emitter layer 911D to a thickness 961D of 100 nm and is doped with 1×10¹⁹ cm⁻³ silicon atoms.

Reference is now made to FIG. 9E, showing another alternative thin film HET structure in accordance with the invention grown on an amorphous glass substrate 901E. On top of substrate 901E is deposited an aluminum metal collector contacting layer 903E to a thickness 953E of 100 nm. On top of layer 903E is grown the i-GaAs collector layer 905E to a thickness 955E of 0.5 μm and is nominally undoped. On top of layer 905E is grown the n⁺ InAs base layer 907E to a thickness 957E of 25 nm and doped 1×10¹⁷ cm⁻³ silicon atoms. On top of layer 907E is grown the i-Al_{0.25}Ga_{0.75}As emitter layer 909E to a thickness 959E of 100 nm and is nominally undoped. On top of layer 909E is deposited an aluminum metal emitter contacting layer 911E to a thickness 961E of 100 nm.

Reference is now made to FIG. 9F, showing another alternative thin film HET in accordance with the invention. On top of substrate 901F is deposited a polysilicon layer 903F doped n-type with a doping density of 1×10²⁰ cm⁻³ to a thickness 953F of 1000 nm. Those skilled in the art will recognize that various techniques may be used to improve the quality of polysilicon layer 903F, including flash annealing, laser annealing, hot gas annealing, and various planarization techniques such as chemical mechanical planarization (CMP). On top of layer 903F is grown an i-GaAs collector layer 905F to a thickness 955F of 1000 nm and is nominally undoped. On top of layer 905F is grown the n⁺ InAs base layer 907F to a thickness 957F of 10 nm and doped 1×10¹⁹ cm⁻³ silicon atoms. On top of layer 907F is grown deposited a Si₃N₄ emitter layer 909F to a thickness 959F of 10 nm. To achieve high quality in the emitter layer 909F requires a high performance deposition technique such as Jet Vapor Deposition (T. P. Ma, “Making Silicon Nitride Film a Viable Gate Dielectric,” IEEE Trans. Electron Devices, v. 45, p. 680 (1998)). On top of layer 909F is deposited an aluminum metal emitter contacting layer 911F to a thickness 961F of 100 nm.

We claim:

1. A heterojunction diode including a first side and a second side, wherein said first side contains at least 10⁷ dislocations and/or grain boundaries per cm².

2. The heterojunction diode of claim 1 wherein said first side includes a compound semiconductor material containing at least 25% In atoms.

3. The heterojunction diode of claim 2 wherein said semiconductor material includes atoms from columns III and from column V of the periodic table.

4. The heterojunction diode of claim 1 wherein said first side contains amorphous semiconductor material.

5. The heterojunction diode of claim 1 wherein said second side also exhibits a density of dislocations of at least 10⁷ per cm², a density of polycrystalline grains of at least 10⁷ per cm², amorphous semiconductor material, or some combination of these.

6. A field-effect transistor including a gate electrode, said electrode using at least one heterojunction diode in accordance with claim 1.

7. A hot-electron transistor including a junction, said junction using a heterojunction diode in accordance with claim 1.

8. A photodetector including a junction, said junction using a heterojunction diode in accordance with claim 1.

9. A metal-semiconductor-metal junction wherein said semiconductor exhibits at least 10⁷ dislocations or grain boundaries per cm².

10. A junction in accordance with claim 9 wherein at least one of said metals is a semi-metal.

11. A junction in accordance with claim 10 wherein said semi-metal includes at least 25% In atoms.

12. A diode junction including at least 10⁷ dislocations or grain boundaries per cm², said diode junction acting as a Schottky, a PN, an nN isotype heterojunction, an MIM, an NIN, a PIP, a PIN, or a metal-semiconductor contact.

13. A diode junction in accordance with claim 12 including amorphous semiconductor material.

14. A diode junction in accordance with claim 12 including atoms from column III and from column V of the periodic table.

15. A diode junction in accordance with claim 15 wherein said first side includes at least 25% In atoms.

16. A microelectronic device including a plurality of diode junctions in accordance with claim 12.

17. A transistor in accordance with claim 16.

18. The transistor of claim 17 wherein said transistor is a MESFET, JFET, HFET, HEMT, pHEMT, or fin FET.

19. The transistor of claim 17 wherein said transistor is a junction transistor.

20. The transistor of claim 17 wherein said junction transistor is a BJT, HBT, or metal-base transistor.
